(19) United States
(12) Patent Application Publication
(10) Pub. No.: US 2026/0321555 A1
(43) Pub. Date: Oct. 15, 2026

(54) PLASMA PROCESSING APPARATUS AND PLASMA PROCESSING METHOD

(71) Applicant: Hitachi High-Tech Corporation, Tokyo (JP)

(72) Inventors: Shintarou NAKATANI, Tokyo (JP); Takamasa Ichino, Tokyo (JP); Yuki Kondo, Tokyo (JP)

(21) Appl. No.: 19/723,309

(22) Filed: Jun. 29, 2026

Related U.S. Application Data
(63) Continuation of application No. 17/641,871, filed on Mar. 24, 2021, now abandoned.

(51) Int. Cl. H01J 37/32; H10P 50/24

(52) U.S. Cl. CPC H01J 37/32715; H01J 37/32082; H01J 37/32541; H01J 37/32642; H10P 50/242; H01J 2237/334

(57) ABSTRACT

A plasma processing apparatus includes a sample stage including a placement surface on which a semiconductor wafer is placed, a ring-shaped thin film electrode surrounding the sample stage, and a susceptor ring made of a dielectric covering the thin film electrode, in which the thin film electrode includes a first portion located lower than the rear surface of the semiconductor wafer, a second portion located higher than the main surface of the semiconductor wafer, and a third portion connecting the first portion and the second portion, and the first portion of the thin film electrode has an overlap region that overlaps the semiconductor wafer in a plan view.

### DESCRIPTION

### TECHNICAL FIELD

The present invention relates to a plasma processing apparatus and a plasma processing method, and specifically to a plasma processing apparatus and a plasma processing method suitable for machining a material to be processed such as a semiconductor wafer.

### BACKGROUND ART

Generally, dry etching using plasma is performed in a semiconductor manufacturing process. A plasma processing apparatus for performing dry etching uses various techniques.

The plasma processing apparatus generally includes a vacuum processing chamber, a gas supply apparatus connected thereto, an evacuation system that maintains pressure in the vacuum processing chamber at a desired value, an electrode on which a semiconductor wafer to be processed is placed, a plasma generating means for generating a plasma in the vacuum processing chamber, and the like. The etching processing is performed on the semiconductor wafer held by the wafer replacement electrode by bringing processing gas into a plasma state by the plasma generating means, the processing gas being supplied from a shower plate or the like into the vacuum processing chamber.

Recently, with improvement of integration of semiconductor devices, circuit structure becomes finer, and therefore it is required to improve micromachining, i.e., machining accuracy. Furthermore, in order to improve acquisition rate of non-defective semiconductor devices per semiconductor wafer, there is a need for a plasma processing apparatus capable of manufacturing non-defective semiconductor devices on an area of the semiconductor wafer closer to its circumferential portion.

In order to suppress deterioration of performance of the semiconductor wafer in its circumferential portion, it is important to reduce concentration of an electric field at the peripheral region of the semiconductor wafer placed on the sample stage. For example, in a case of an etching processing, it is required to control sudden increase of a processing speed (etching rate) at the circumferential portion of the semiconductor wafer. To this end, it is required to make thickness of a sheath uniform from the center of the semiconductor wafer to the peripheral region thereof, the sheath being formed above the semiconductor wafer during processing of the semiconductor wafer.

Japanese Unexamined Patent Application Publication No. 2020-43100 (Patent Literature 1) discloses a technology of improving uniformity of plasma processing to the circumferential portion of the semiconductor wafer by providing an electrically conductive thin film electrode to a part of an insulating ring surrounding an outer periphery of the sample stage on which the semiconductor wafer is placed, applying a first high-frequency power to the sample stage, and applying a second high-frequency power to the thin film electrode.

Japanese Unexamined Patent Application Publication No. 2010-283028 (Patent Literature 2) discloses a technology of controlling an ion incident angle and improving a balance between reduction of deposit and processing result by providing a dielectric ring surrounding the outer periphery of the sample stage on which the semiconductor wafer is placed and an electrically conductive ring disposed thereon, the electrically conductive ring being integrally constituted by an outer ring having a top surface higher than the wafer and an inner ring having a top surface lower than the wafer, and applying direct voltage to the electrically conductive ring.

### Citation List

### Patent Literature

Patent Literature 1: Japanese Unexamined Patent Application Publication No. 2020-43100

Patent Literature 2: Japanese Unexamined Patent Application Publication No. 2010-283028

### SUMMARY OF INVENTION

### Technical Problem

According to Patent Literature 1, the insulating ring having the thin film electrode formed thereon to apply high-frequency power is constructed so as to be covered by a susceptor ring made of a dielectric except a sample stage placement surface in order to suppress electrical interference with high-frequency power applied to the sample stage from another system. Accordingly, it is difficult to bring an inner peripheral end of the thin film electrode close to an end portion of the wafer, which requires further consideration for preferably controlling the electric field around the wafer end portion.

Moreover, according to Patent Literature 2, because of lack of a protective ring that covers the surrounding of the electrically conductive ring, temperature of the electrically conductive ring is increased by the electrically conductive ring contacting a plasma. Consideration is required in terms of the fact that an effect thereby may reduce reliability of the apparatus and fact that fabricated shapes may vary as a result of ununiform temperature of the wafer to be processed due to the effect of heat generation.

That is, there is a need for a plasma processing method that allows for improving reliability of the plasma processing apparatus or improving yield of the semiconductor wafer to be processed.

Other problems and novel features will become apparent from description herein and accompanying drawings.

### Solution to Problem

A plasma processing apparatus according to one embodiment includes a sample stage including a placement surface having a first circular shape in a plan view where a semiconductor wafer is placed, a dielectric ring surrounding the sample stage in a peripheral region of the sample stage and equipped with a ring-shaped thin film electrode including an inner peripheral end and an outer peripheral end in a plan view, and a susceptor ring made of a dielectric placed on the dielectric ring and covering the thin film electrode, the semiconductor wafer includes a main surface and a rear surface having a second circular shape in a plan view and an end portion being an arc portion of the main surface, a first radius of the first circular shape is smaller than a second radius of the second circular shape, the thin film electrode includes, between the inner peripheral end and the outer peripheral end, a first portion located lower than the rear surface of the semiconductor wafer, a second portion located higher than the main surface of the semiconductor wafer, and a third portion connecting the first portion and the second portion, and the first portion of the thin film electrode has an overlap region that overlaps the semiconductor wafer in a plan view.

Moreover, a plasma processing method according to one embodiment includes the steps of: (a) preparing a plasma processing apparatus that includes a sample stage, a ring-shaped thin film electrode arranged on an outer periphery of the sample stage, and a high frequency power source; (b) placing a semiconductor wafer having a main surface and a rear surface on the sample stage; and (c) performing plasma processing on the main surface of the semiconductor wafer, the thin film electrode includes a first portion located lower than the rear surface of the semiconductor wafer, a second portion located higher than the main surface of the semiconductor wafer, and a third portion connecting the first portion and the second portion, the first portion of the thin film electrode has an overlap region that overlaps the semiconductor wafer in a plan view, and, at the step (c), high-frequency power is supplied from the high frequency power source to the sample stage and the thin film electrode.

### Advantageous Effects of Invention

According to one embodiment, it is possible to improve reliability of the plasma processing apparatus. Moreover, it is possible to improve yield of an object to be processed in the plasma processing.

### BRIEF DESCRIPTION OF DRAWINGS

FIG. 1 is a cross-sectional view schematically showing an outline of a configuration of a plasma processing apparatus according to one embodiment;

FIG. 2 is a cross-sectional view showing a peripheral portion of a wafer replacement electrode in the plasma processing apparatus according to one embodiment;

FIG. 3 is a plan view showing the wafer replacement electrode in the plasma processing apparatus according to one embodiment;

FIG. 4 is a cross-sectional view taken along a line X-X in FIG. 3;

FIG. 5 is a cross-sectional view showing the peripheral portion of the wafer replacement electrode in the plasma processing apparatus according to a first modification; and

FIG. 6 is a cross-sectional view schematically showing an outline of the configuration of the plasma processing apparatus being a second modification.

### DESCRIPTION OF EMBODIMENTS

In the following, embodiments are described in detail with reference to drawings. It is to be noted that, through all the drawings for describing the embodiments, members having the same functionalities are denoted with the same reference numerals, and repeated description thereof is omitted. Moreover, in the following embodiments, the same or similar parts are not described repeatedly unless specifically required.

### Embodiments

### Plasma Processing Apparatus

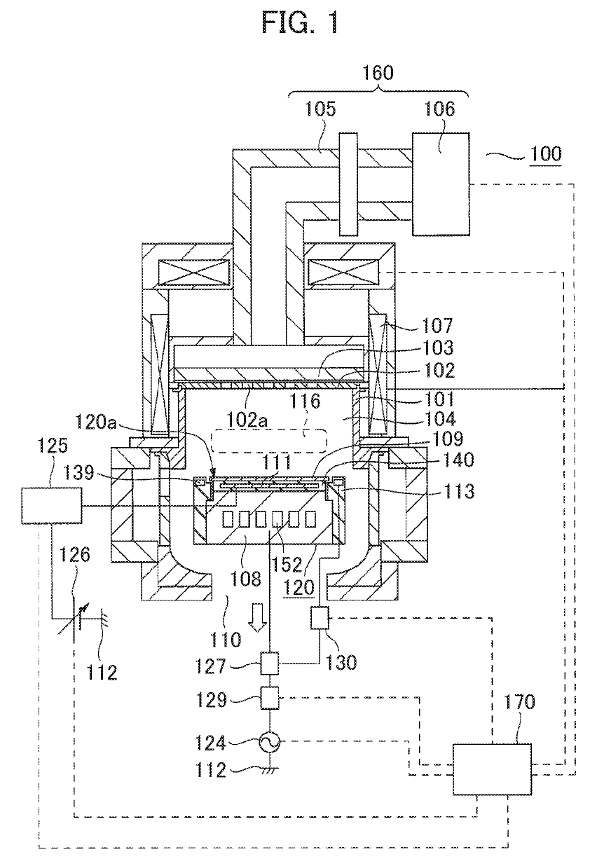

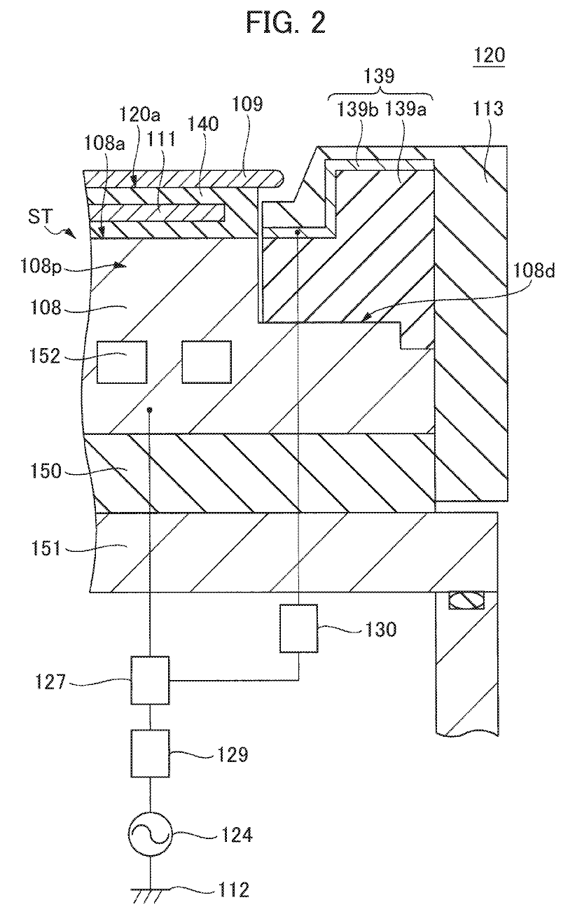

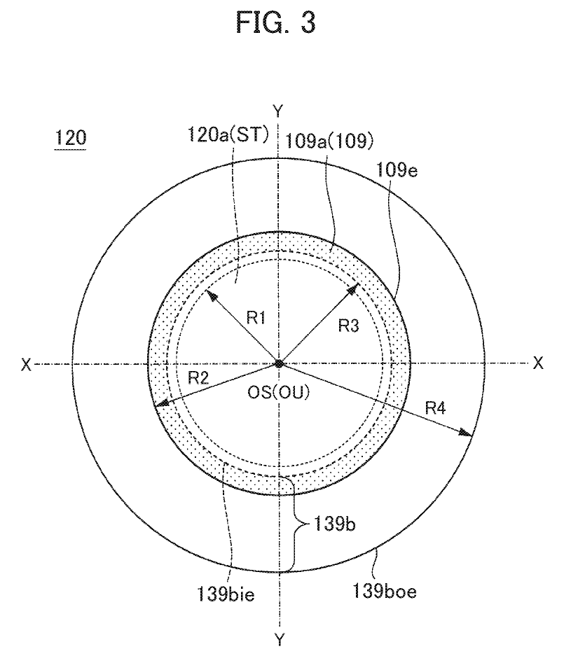

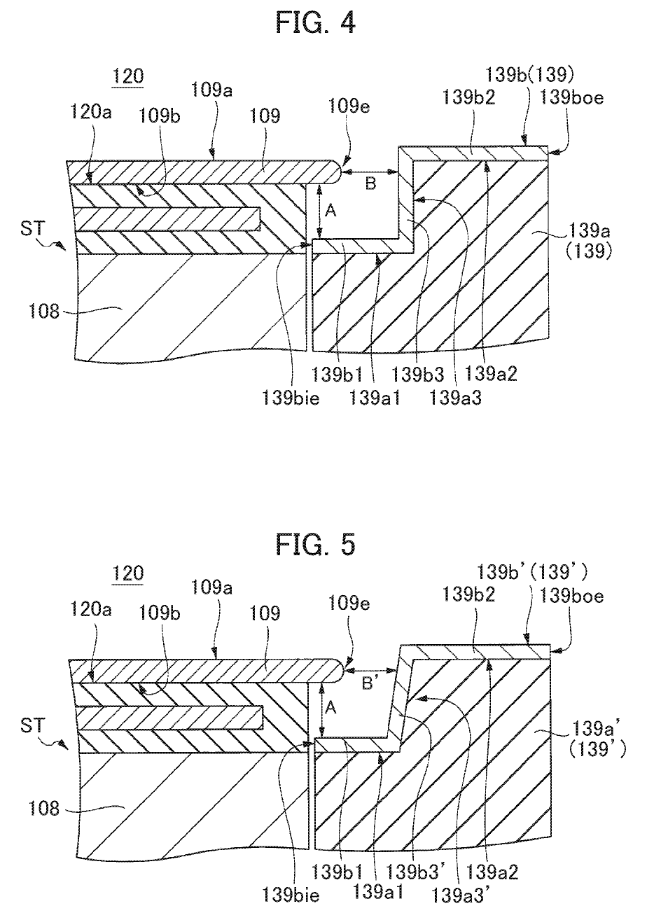

In the following, a plasma processing apparatus according to the present embodiment is described with reference to FIGS. 1 to 4. FIG. 1 is a cross-sectional view schematically showing an outline of a configuration of a plasma processing apparatus according to the present embodiment, FIG. 2 is a cross-sectional view showing a peripheral portion of an wafer replacement electrode in the plasma processing apparatus according to the present embodiment, FIG. 3 is a plan view showing the wafer replacement electrode in the plasma processing apparatus according to the present embodiment, and FIG. 4 is a cross-sectional view taken along a line X-X in FIG. 3

FIG. 1 shows a plasma etching apparatus 100 as an example of the plasma processing apparatus. The plasma etching apparatus 100 uses a microwave electric field as an electric field for forming a plasma, forms the plasma by causing an ECR (Electron Cyclotron Resonance) with the microwave electric field and the magnetic field, and performs etching processing on a substrate sample such as a semiconductor wafer using the plasma.

The plasma etching apparatus 100 has a vacuum vessel 101 including a processing chamber 104 therein in which the plasma is formed. A disk-shaped dielectric window 103 (e.g., made of quartz) is placed as a lid member on the processing chamber 104, an upper part of which has a cylindrical shape, thereby forming a part of the vacuum vessel 101. A seal member such as an O-ring is arranged between the cylindrical vacuum vessel 101 and the dielectric window 103, whereby airtightness is secured inside the vacuum vessel 101 or the processing chamber 104.

Moreover, an evacuation port 110 connected to the processing chamber 104 is disposed below the vacuum vessel 101, in communication with an evacuation apparatus (not shown in the figure) connected to be arranged below the vacuum vessel 101. Furthermore, a shower plate 102 is disposed below the dielectric window 103, which constitutes a circular ceiling surface of the processing chamber 104. The shower plate 102 has a disk shape with a plurality of gas introducing holes 102a passing therethrough in the central portion, and gas for etching processing is introduced to the processing chamber 104 through the gas introducing holes 102a. The shower plate 102 is constituted by a dielectric material such as quartz.

Arranged above the vacuum vessel 101 is an electric field/magnetic field forming unit 160 that forms an electric field and a magnetic field to generate a plasma 116. The electric field/magnetic field forming unit 160 includes a waveguide tube 105 and an electric field generating power source 106, and a high-frequency electric field oscillated from the electric field generating power source 106 is propagated through the waveguide tube 105 to be introduced into the processing chamber 104. As a frequency of the electric field, for example, a microwave of 2.45 GHz is used.

A magnetic field generating coil 107 is arranged around a lower end portion of the waveguide tube 105 and around the vacuum vessel 101. The magnetic field generating coil 107 is constituted by an electromagnet supplied with a direct current to form a magnetic field and a yoke.

With the processing gas introduced from the gas introducing holes 102a in the shower plate 102 into the processing chamber 104, the microwave electric field oscillated from the electric field generating power source 106 propagates inside the waveguide tube 105 and passes through the dielectric window 103 and the shower plate 102 to be supplied to the processing chamber 104 downward from above. Furthermore, the magnetic field caused by the direct current supplied from the magnetic field generating coil 107 is supplied into the processing chamber 104, causes an interaction with the microwave electric field, and causes the ECR (Electron Cyclotron Resonance). The ECR excites, dissociates, or ionizes atoms or molecules in the processing gas, which generates a high-density plasma 116 in the processing chamber 104.

A wafer replacement electrode 120 is arranged below the space in which the plasma 116 is formed. The wafer replacement electrode 120 includes a cylindrical protruding (convex) portion where the top surface of the central portion thereof is formed to be higher than the top surface of the outer periphery, and includes a placement surface 120a on the top surface of the convex portion where a semiconductor wafer (hereinafter, also referred to simply as “wafer”) 109 is placed, the wafer being a sample (processing object). The placement surface 120a is arranged to face the shower plate 102 or the dielectric window 103.

As shown in FIG. 2, the wafer replacement electrode 120 includes an electrode substrate 108, a dielectric film 140 disposed on the electrode substrate 108, an insulating plate 150 and a ground plate 151 disposed below the electrode substrate 108a dielectric ring 139, and a susceptor ring 113.

The electrode substrate 108 includes a convex portion (protrusion) 108p and a concave portion (recess) 108d. The convex portion 108p that is circular in a plan view is located in the central portion of the electrode substrate 108around which the ring-shaped concave portion 108d is located. The convex portion 108p has a top surface 108a with a circular shape in a plan view, and the top surface 108a is covered with the dielectric film 140. The dielectric film 140 has the placement surface 120a, and the semiconductor wafer 109 is placed on the placement surface 120a. The placement surface 120a has a circular shape in a plan view, its radius is equal to the radius of the top surface 108a, and the centers of both of the circular shapes overlap each other.

Arranged inside the dielectric film 140 is a conductive film 111 that is a film made of a plurality of dielectrics. As shown in FIG. 1, the conductive film 111 is connected to a DC power source 126 via a high pass filter 125. When direct current power is supplied to the conductive film 111, the semiconductor wafer 109 is attracted to the placement surface 120a via the dielectric film 140 on the conductive film 111. The conductive film 111 is an electrode for electrostatic attraction. For convenience, the convex portion (protrusion) 108p of the electrode substrate 108 and the dielectric film 140 including the conductive film 111 are collectively referred to as a sample stage ST.

The electrode substrate 108 is connected to a high frequency power source 124 via a branch box 127 and a matching device 129. The high frequency power source 124 and the matching device 129 are arranged closer than a distance between the high pass filter 125 and the conductive film 111. Furthermore, the high frequency power source 124 is grounded to a ground 112.

During the processing of the semiconductor wafer 109, high-frequency power at a predetermined frequency is supplied from the high frequency power source 124 to the electrode substrate 108 (i.e., the sample stage ST). A bias potential having a distribution corresponding to difference between a potential of the plasma 116 and a potential of the electrode substrate 108 is formed above the semiconductor wafer 109 attracted and held by the placement surface 120a via the dielectric film 140.

The electrode substrate 108 includes therein a refrigerant flow passage 152 arranged multiply in a helical or concentric manner around a vertical center axis of the electrode substrate 108 to cool the wafer replacement electrode 120, an inlet to and an outlet from the wafer replacement electrode 120 are connected by a temperature regulator that includes an unshown refrigeration cycle and regulates the refrigerant to a predetermined temperature range by heat transfer and a conduit line, and the refrigerant of which temperature changed after having passed through the refrigerant flow passage 152 flows out of the outlet, passes through the flow passage inside the temperature regulator via the conduit line to be within the predetermined temperature range, and then is supplied to the refrigerant flow passage 152 in the electrode substrate 108 for circulation.

The ring-shaped dielectric ring 139 surrounding the convex portion 108p is placed on the concave portion 108d of the electrode substrate 108 and the susceptor ring 113 is placed on the dielectric ring 139. The dielectric ring 139 and the susceptor ring 113 are constituted by a dielectric material like ceramics such as quartz or alumina, for example. Because a side surface of the electrode substrate 108 and a bottom surface of the concave portion 108b are covered by at least the dielectric ring 139 or the susceptor ring 113, the electrode substrate 108 can be prevented from being damaged by the plasma. Moreover, a surface of the dielectric ring 139 in contact with the susceptor ring 113 is constituted by a rough surface having a surface roughness RA of, for example, 1.0 or higher. In this manner, heat transfer from the susceptor ring 113 that is heated by being in contact with the plasma to the dielectric ring 139 is suppressed.

The dielectric ring 139 is constituted by a dielectric ring 139a and a thin film electrode 139b, and the thin film electrode 139b is formed on a stepped top surface of the dielectric ring 139a. The thin film electrode 139b is connected to the branch box 127 via a load impedance variable box 130. That is, the electrode substrate 108 of the sample stage ST on which the semiconductor wafer 109 is placed and the thin film electrode 139b of the dielectric ring 139 are connected to the high frequency power source 124 that is a single power supply, and the high-frequency power is supplied from the high frequency power source 124 to the electrode substrate 108 and the thin film electrode 139b.

The wafer replacement electrode 120 includes the disk-shaped insulating plate 150 abutting a lower surface of the electrode substrate 108 and the ground plate 151 that is a disk-shaped conductor member arranged abutting the lower surface of the insulating plate 150 and set to the ground potential.

As shown in FIG. 1, the electric field generating power source 106, the magnetic field generating coil 107, the high frequency power source 124, high pass filter 125, the DC power source 126, the branch box 127, the matching device 129, and the load impedance variable box 130 are connected by wire or wirelessly to a controller 170.

The placement surface 120a of the sample stage ST, the semiconductor wafer 109 and the thin film electrode 139b are described with reference to the plan view of FIG. 3 and the cross-sectional view of FIG. 4. It is to be noted that, as shown in FIG. 4, the semiconductor wafer 109 has a main surface 109a on which the plasma processing is performed, a rear surface 109b to be in contact with the placement surface 120a, and an end portion 109e that is the arc portion of the main surface 109a.

As shown in FIG. 3, the placement surface 120a has a circular shape with a radius R1 from a center OS. The ring-shaped thin film electrode 139b has an inner peripheral end 139bie having a circular shape with a radius R3 from the center OS and an outer peripheral end 139boe having a circular shape with a radius R4 from the center OS. Moreover, the main surface 109a of the semiconductor wafer 109 (in other words, the end portion 109e) has a circular shape with a radius R2 from a center OU. It is to be noted that, although the center OU may possibly be offset from the center OS due to “misalignment” when mounting the semiconductor wafer 109 on the placement surface 120a, FIG. 3 shows an aligned case. Even when there is the “misalignment”, the plasma processing is performed as long as it is within an allowable range. The radius R2 of the main surface 109a of the semiconductor wafer 109 is larger than the radius R1 of the placement surface 120a (R2>R1). Moreover, the radius R4 of the outer peripheral end 139boe of the thin film electrode 139b is larger than the radius R3 of the inner peripheral end 139bie (R4>R3). A feature of the present embodiment is that the radius R3 of the inner peripheral end 139bie of the thin film electrode 139b is smaller than the radius R2 of the end portion 109e of the semiconductor wafer 109 (R3<R2). That is, in a plan view, the thin film electrode 139b and the semiconductor wafer 109 have this “overlap region (a hatched region in FIG. 3)”. The “overlap region” encompasses the whole area of the arc-shaped end portion 109e of the semiconductor wafer 109. If the aforementioned “misalignment” occurs and the center OU offsets from the center OS at all, the “overlap region” is secured for the whole area of the arc-shaped end portion 109e of the semiconductor wafer 109.

As shown in FIG. 4, the top surface of the dielectric ring 139a includes a first surface 139a1, a third surface 139a3, and a second surface 139a2 arranged in a stepped manner. The first surface 139a1 and the second surface 139a2 are horizontal planes parallel to the main surface 109a of the semiconductor wafer 109 or the placement surface 120a, and the third surface 139a3 is a plane connecting the first surface 139a1 and the second surface 139a2 and perpendicular to the main surface 109a of the semiconductor wafer 109 or the placement surface 120a. Provided on the top surface of the dielectric ring 139a is the thin film electrode 139b. It is to be noted that an insulating film may be provided on the top surface of the dielectric ring 139a and the thin film electrode 139b may be formed thereon.

The thin film electrode 139b is constituted by a conductive film such as a thermal spraying film of tungsten, for example. The ring-shaped thin film electrode 139b has a ring width extending from the inner peripheral end 139bie to the outer peripheral end 139boe and has a first portion 139b1, a third portion 139b3, and a second portion 139b2 in a width direction. The first portion 139b1, the third portion 139b3, and the second portion 139b2 are formed corresponding to the first surface 139a1, the third surface 139a3, and the second surface 139a2 on the top surface of the dielectric ring 139a, respectively. Accordingly, the first portion 139b1 and the second portion 139b2 are horizontal planes parallel to the main surface 109a of the semiconductor wafer 109 or the placement surface 120a, and the third portion 139b3 is a vertical plane connecting the first portion 139b1 and the second portion 139b2. Moreover, the first portion 139b1 is located lower than the rear surface 109b of the semiconductor wafer 109 in the vertical direction as a whole, and the inner peripheral end 139bie is located below the semiconductor wafer 109 and overlaps the semiconductor wafer 109. The first portion 139b1 is spaced from the rear surface 109b of the semiconductor wafer 109 by a distance A in the vertical direction and has the “overlap region” between itself and the semiconductor wafer 109 in a plan view. The second portion 139b2 is located higher than the main surface 109a of the semiconductor wafer 109 as a whole. Moreover, the third portion 139b3 is spaced from the end portion 109e of the semiconductor wafer 109 by a distance B in a horizontal direction. A feature of the present embodiment is that the distance A is smaller than the distance B. The horizontal direction is a direction perpendicular to the vertical direction and parallel to the placement surface 120a or the main surface 109a of the semiconductor wafer 109.

It is to be noted that, as shown in FIG. 2, the first portion 139b1, the third portion 139b3, and the second portion 139b2 of the thin film electrode 139b are covered by the susceptor ring 113 on their surfaces (top surfaces). The susceptor ring 113 includes a horizontal plane higher than the main surface 109a of the semiconductor wafer 109above the second portion 139b2.

### Plasma Processing Method

Now, the plasma processing method using the aforementioned plasma etching apparatus 100 is described.

First, the aforementioned plasma etching apparatus 100 is prepared.

Then, a step of carrying in the semiconductor wafer 109 follows. A vacuum transport chamber with a pressure reduced to be similar to that in the processing chamber 104 is coupled to a side wall of the vacuum vessel 101. The semiconductor wafer 109 is placed on an arm tip of a wafer transport robot arranged in the vacuum transport chamber and carried into the processing chamber 104. The semiconductor wafer 109 is then placed on the placement surface 120a and held by the sample stage ST by electrostatic attraction.

A step of introducing etching gas step follows next. After the transport robot is retracted into the vacuum transport chamber, the inside of the processing chamber 104 is sealed. In this state, the etching processing gas is supplied into the processing chamber 104. The introduced gas is introduced into the processing chamber 104 through the gas introducing holes 102a in the shower plate 102. Gas and particles are exhausted out of the processing chamber 104 through the evacuation port 110 by an operation of the evacuation apparatus coupled to the evacuation port 110. Depending on the balance between a supply volume of the gas from the gas introducing holes 102a in the shower plate 102 and exhaust volume from the evacuation port 110, the inside of the processing chamber 104 is adjusted to a predetermined pressure suitable for processing the semiconductor wafer 109.

A plasma etching (plasma processing) step follows next. Although details are omitted, after adjusting temperature of the semiconductor wafer 109 as required, the microwave electric field and the magnetic field are supplied into the processing chamber 104 and the plasma 116 is generated using the gas. When the plasma 116 is formed, a high frequency (RF) power is supplied from the high frequency power source 124 to the electrode substrate 108, the bias potential is formed above the main surface 109a of the semiconductor wafer 109, and charged particles such as ions in the plasma 116 are attracted to the main surface 109a of the semiconductor wafer 109 depending on the potential difference from the plasma 116. Furthermore, the charged particles impinge on a surface of a film layer to be processed that is arranged on the main surface 109a of the semiconductor wafer 109 in advance to perform the etching processing. Moreover, as described with reference to FIGS. 2 to 4, the high frequency (RF) power is supplied to the thin film electrode 139b provided to the dielectric ring 139 from the high frequency power source 124 via the matching circuit 129, the branch box 127, and the load impedance variable box 130. It is to be noted that, during the etching processing, the processing gas introduced into the processing chamber 104 and particles of a reaction product produced during the processing are exhausted from the evacuation port 110.

A step of carrying out the semiconductor wafer 109 follows next. The semiconductor wafer 109 having been subjected to the etching processing is supported by the arm tip of the aforementioned transport robot to be carried out of the processing chamber 104.

### Feature of The Present Embodiment

During the processing of the semiconductor wafer 109, the plasma processing apparatus according to the present embodiment supplies the high-frequency power from a single high frequency power source 124 to the electrode substrate 108 of the sample stage ST and the thin film electrode 139b provided to the dielectric ring 139. The high-frequency power output from the high frequency power source 124 is supplied to the thin film electrode 139b arranged inside the susceptor ring 113 via the load impedance variable box 130 on which a power supply passage is arranged, the power supply passage electrically connecting between the branch box 127 and the thin film electrode 139b. At this time, by regulating impedance on the power supply passage to a value within a preferable range in the load impedance variable box 130, with regard to an impedance portion that is relatively higher in an upper portion of the susceptor ring 113, a value of impedance is made relatively lower with respect to the high-frequency power from the high frequency power source 124 to the circumferential portion of the semiconductor wafer 109 via the branch box 127 through the electrode substrate 108. This makes it possible to effectively supply the high-frequency power to the circumferential portion and the peripheral region of the semiconductor wafer 109 and to mitigate concentration of the electric field in the circumferential portion and the peripheral region of the semiconductor wafer 109, thereby making distribution of height of equipotential surfaces for the bias potential uniform above these regions. Accordingly, it is possible to improve reliability of the plasma processing apparatus and to improve yield of the plasma processing on the semiconductor wafer 109.

Moreover, the thin film electrode 139b includes the first portion 139b1 located lower than the rear surface 109b of the semiconductor wafer 109, the second portion 139b2 located higher than the main surface 109a of the semiconductor wafer 109, and the third portion 139b3 connecting the first portion 139b1 and the second portion 139b2. In a plan view, the first portion 139b1 has the “overlap region” that overlaps the semiconductor wafer 109. Moreover, the first portion 139b1 is spaced from the rear surface 109b by the distance A in the vertical direction, the third portion 139b3 is spaced from the end portion 109e of the semiconductor wafer 109 by the distance B in the horizontal direction, and the distance A is smaller than the distance B.

A sheath potential distribution in the peripheral region of the semiconductor wafer 109 obtained by supplying the high-frequency power to the thin film electrode 139b is mostly formed by the first portion 139b1 and the second portion 139b2. This potential distribution can increase electric field strength by bringing the first portion 139b1 and the second portion 139b2 close to the semiconductor wafer 109, thereby extending a control area of the sheath potential. However, when the third portion 139b3 is brought too close to the semiconductor wafer 109, the sheath potential distribution becomes to have a steep gradient along the shape of the susceptor ring 113 near the end portion 109e of the semiconductor wafer 109, which is not suitable as the control area. On the other hand, when the first portion 139b1 is brought close to the rear surface 109b of the semiconductor wafer 109, the sheath potential distribution is affected only near the end portion 109e of the semiconductor wafer 109, presenting better controllability than the case in which the third portion 139b3 is brought too close. From the above, in order to have a preferable sheath potential control area, it is desired that the distance A should be smaller than the distance B (A<B).

Moreover, because the dielectric ring 139 including the thin film electrode 139b is covered with the dielectric susceptor ring 113 on its top surface and cannot contact the plasma 116, it is possible to suppress excessive temperature rise. Furthermore, because the surface of the dielectric ring 139 to be in contact with the susceptor ring 113 is constituted by the rough surface (e.g., 1.0 or higher surface roughness RA), it is possible to suppress heat transfer from the susceptor ring 113 that is heated by being in contact with the plasma to the dielectric ring 139. Accordingly, it is possible to improve reliability of the plasma processing apparatus and to improve production yield of the semiconductor wafer 109.

Moreover, by supplying the high-frequency power from the single high frequency power source 124 to the electrode substrate 108 of the sample stage ST and the thin film electrode 139b provided to the dielectric ring 139, it is possible to suppress electrical interference between the high-frequency power applied to the electrode substrate 108 and the high-frequency power applied to the thin film electrode 139b. It is possible to bring the inner peripheral end 139bie of the thin film electrode 139b close to the sample stage ST below the rear surface 109b of the semiconductor wafer 109 and to bring the first portion 139b1 and the second portion 139b2 of the thin film electrode 139b close to the semiconductor wafer 109. As a result, preferable electric field control and sheath potential control become possible in the circumferential portion and the peripheral region of the semiconductor wafer 109, thereby achieving an effect of improving reliability of the plasma processing apparatus and improving yield of the semiconductor wafer 109.

### First Modification

FIG. 5 is a cross-sectional view showing the peripheral portion of the wafer replacement electrode in the plasma processing apparatus according to a first modification. FIG. 5 is a modification of FIG. 4.

A dielectric ring 139’ has a shape different from that shown in FIG. 4 of the above-described embodiment. A top surface of the dielectric ring 139a’ includes the first surface 139a1, a third surface 139a3’, and the second surface 139a2. The third surface 139a3’ has an inclination larger than 90° with respect to the first surface 139a1 and the second surface 139a2. The third surface 139a3’ has an inclination that gets closer to the sample stage ST along the vertical direction.

A ring-shaped thin film electrode 139b’ has a ring width extending from the inner peripheral end 139bie to the outer peripheral end 139boe, and has the first portion 139b1, a third portion 139b3’, and the second portion 139b2 in the width direction. The first portion 139b1, the third portion 139b3’, and the second portion 139b2 are formed corresponding to the first surface 139a1, the third surface 139a3’, and the second surface 139a2 on the top surface of the dielectric ring 139a’, respectively. Accordingly, the third portion 139b3’ has the inclination that gets closer to the sample stage ST along the vertical direction.

Also in the first modification, as in the above-described embodiment, the first portion 139b1 has the “overlap region” between itself and the semiconductor wafer 109 in a plan view. Moreover, the first portion 139b1 is spaced from the rear surface 109b by the distance A in the vertical direction, the third portion 139b3’ is spaced from the end portion 109e of the semiconductor wafer 109by a distance B’ in the horizontal direction, and the distance A is smaller than the distance B’.

According to the first modification, as compared to the above-described embodiment, it is possible to bring a lower portion of the third portion 139b3’ closer to the end portion 109e of the semiconductor wafer 109 accordingly, it is possible to affect the sheath potential distribution around the end portion 109e of the semiconductor wafer 109 and to change the heath potential control area.

### Second Modification

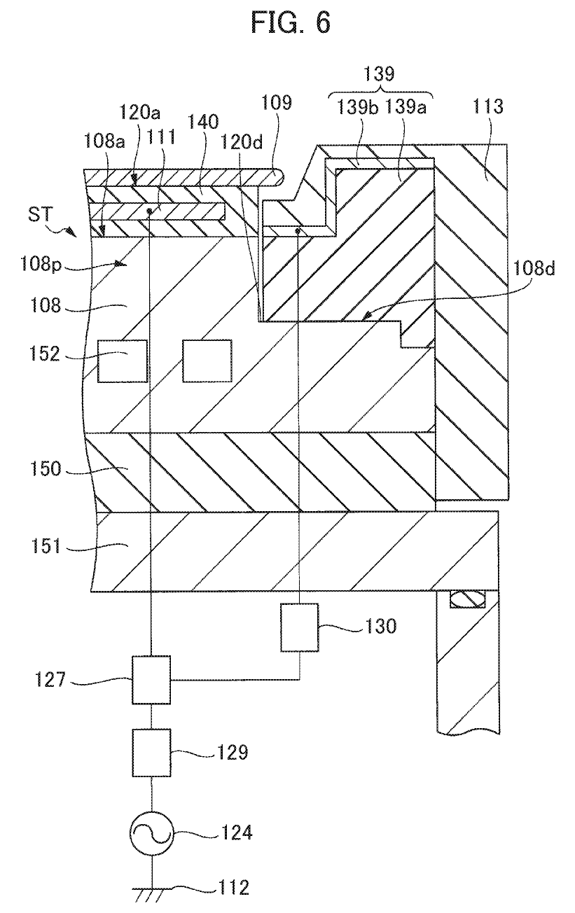

FIG. 6 is a cross-sectional view schematically showing an outline of the configuration of the plasma processing apparatus being a second modification. A supply destination of high-frequency power is different from that shown in FIG. 2 of the above-described embodiment. In the second modification, the high frequency power source 124 is connected to the conductive film 111 via the matching device 129 and the branch box 127.

Also in the configuration shown in FIG. 6, by correcting the difference of the load impedance from the configuration shown in FIG. 2 by appropriately changing the high-frequency power value by the high frequency power source 124, the sheath potential distribution in the circumferential portion and the peripheral region of the semiconductor wafer 109 formed by the conductive film 111 is made similar to the sheath potential distribution in the case shown in FIG. 2, thereby obtaining an effect similar to that in the above-described embodiment.

Moreover, in the above-described embodiment or modification, an etched film arranged on the main surface of the semiconductor wafer 109 in advance before processing is a silicon oxide film, and methane tetrafluoride gas, oxygen gas, or trifluoromethane gas is used as processing gas for etching and cleaning gas for cleaning. Moreover, as the etched film, not only the silicon oxide film but also a polysilicon film, a photoresist film, an organic antireflection film, an inorganic antireflection film, an organic material, an inorganic material, a silicon oxide film, a silicon oxide nitride film, a silicon nitride film, a LOW-K material, a HIGH-K material, an amorphous carbon film, an SI substrate, a metal material, and the like may be used, which provide similar effects.

Moreover, as the processing gas for etching, chlorine gas, hydrogen bromide gas, methane tetrafluoride gas, methane trifluoride gas, methane bifluoride gas, argon gas, helium gas, oxygen gas, nitrogen gas, carbon dioxide gas, carbon monoxide gas, hydrogen gas, or the like may be used. Furthermore, as the processing gas for etching, ammonia gas, propane octafluoride gas, nitrogen trifluoride gas, sulfur hexafluoride gas, methane gas, silicon tetrafluoride gas, neon gas, krypton gas, xenon gas, radon gas, or the like may be used.

Although the invention made by the present inventors is specifically described above on the basis of the embodiments, it goes without saying that the present invention is not limited to the embodiments and various modifications may be made without departing from the spirit of the invention. For example, the wafer replacement electrode 120 may include a heater to regulate the temperature of the semiconductor wafer 109 inside the dielectric film 140 or inside the substrate electrode 108. Moreover, for such temperature regulation, at least one temperature sensor may be included to be arranged inside the substrate electrode 108 so as to be capable of communicating with the controller 170 and to detect temperature.

In the above-described embodiment, there is described a configuration of supplying the microwave electric field at the frequency of 2.45 GHz and the magnetic field capable of forming the ECR accordingly in the processing chamber 104 and discharging the processing gas to form the plasma. However, with the configuration described in above-described embodiment, it is possible to achieve workings and effects similar to those described in the above-described embodiments and the like even when the plasma is formed using other types of discharge (effective magnetic field UHF discharge, capacitively coupled discharge, inductively coupled discharge, magnetron discharge, surface wave excited discharge, transfer coupled discharge). Moreover, it is also possible to obtain the similar effects in a case of applying the above-described embodiment, the first modification, and the second modification to the wafer replacement electrode arranged in other plasma processing apparatus for performing the plasma processing, such as a plasma CVD apparatus, an ashing apparatus, a surface modification apparatus, or the like.

### List of Reference Signs

OS: Center

OU: Center

ST: Sample Stage

100: Plasma Etching Apparatus

101: Vacuum Vessel

102: Shower Plate

102a: Gas Introducing Hole

103: Dielectric Window

104: Processing Chamber

105: Waveguide Tube

106: Electric Field Generating Power Source

107: Magnetic Field Generating Coil

108: Electrode Substrate

108a: Top Surface

108d: Concave Portion (Recess)

108p: Convex Portion (Protrusion)

109: Semiconductor Wafer

109a: Main Surface

109b: Rear Surface

109e: End Portion (Arc Portion)

110: Evacuation Port

111: Conductive Film

112: Ground

113: Susceptor Ring

116: Plasma

120: Wafer Replacement Electrode

120a: Placement Surface

120b: Top Surface

124: High Frequency Power Source

125: High Pass Filter

126: Dc Power Source

127: Branch Box

129: Matching Device

130: Load Impedance Variable Box

139: Dielectric Ring

139a: Dielectric Ring

139a1: First Surface

139a2: Second Surface

139a3: Third Surface

139a3´: Third Surface

139b: Thin Film Electrode

139b1: First Portion

139b2: Second Portion

139b3: Third Portion

139b3´: Third Portion

139bie: Inner Peripheral End

139boe: Outer Peripheral End

140: Dielectric Film

150: Insulating Plate

151: Ground Plate

152: Refrigerant Flow Passage

160: Electric Field/Magnetic Field Forming Unit

170: Controller

1. A plasma processing apparatus, comprising:
(a) a sample stage including a placement surface on which a semiconductor wafer is placed and having a first circular shape in a plan view;
(b) a dielectric ring surrounding the sample stage in a peripheral region of the sample stage and equipped with a ring-shaped thin film electrode including an inner peripheral end and an outer peripheral end in a plan view; and
(c) a susceptor ring made of a dielectric placed on the dielectric ring and covering the thin film electrode,
wherein the semiconductor wafer includes a main surface and a rear surface having a second circular shape in a plan view and an end portion being a circumference portion of the main surface,
wherein a first radius of the first circular shape is smaller than a second radius of the second circular shape,
wherein the thin film electrode includes, between the inner peripheral end and the outer peripheral end, a first portion located lower than the rear surface of the semiconductor wafer, a second portion located higher than the main surface of the semiconductor wafer, and a third portion connecting the first portion and the second portion, and
wherein the first portion of the thin film electrode has an overlap region that overlaps the semiconductor wafer in a plan view.

2. The plasma processing apparatus according to claim 1,
wherein the overlap region encompasses the whole area of the circumference portion of the semiconductor wafer.

3. The plasma processing apparatus according to claim 1,
wherein the inner peripheral end of the thin film electrode has a third circular shape with a third radius in a plan view, the third radius being larger than the first radius and smaller than the second radius.

4. The plasma processing apparatus according to claim 1, further comprising:
(d) a single high frequency power source that supplies high-frequency power to the sample stage and the thin film electrode.

5. The plasma processing apparatus according to claim 4,
wherein the sample stage includes a conductive electrode substrate and a dielectric film arranged on the electrode substrate, and
wherein a top surface of the dielectric film constitutes the placement surface.

6. The plasma processing apparatus according to claim 5,
wherein high-frequency power is supplied from the high frequency power source to the electrode substrate.

7. The plasma processing apparatus according to claim 5,
wherein the dielectric film includes a conductive film therein, and
wherein high-frequency power is supplied from the high frequency power source to the conductive film.

8. The plasma processing apparatus according to claim 1,
wherein a first distance between the rear surface of the semiconductor wafer and the first portion of the thin film electrode in a vertical direction is smaller than a second distance between the end portion of the semiconductor wafer and the third portion of the thin film electrode in a horizontal direction.

9. The plasma processing apparatus according to claim 8,
wherein the susceptor ring is interposed between the third portion of the thin film electrode and the end portion of the semiconductor wafer.

10. The plasma processing apparatus according to claim 1,
wherein the first portion and the second portion of the thin film electrode include horizontal planes parallel to the main surface of the semiconductor wafer, and
wherein the third portion of the thin film electrode includes a vertical plane perpendicular to the main surface.

11. The plasma processing apparatus according to claim 1,
wherein the first portion and the second portion of the thin film electrode include horizontal planes parallel to the main surface of the semiconductor wafer, and
wherein the third portion of the thin film electrode includes an inclination that gest closer to the sample stage along the vertical direction.

12. A plasma processing method, comprising the steps of:
(a) preparing a plasma processing apparatus that includes a sample stage, a ring-shaped thin film electrode arranged on an outer periphery of the sample stage, and a high frequency power source;
(b) placing a semiconductor wafer having a main surface and a rear surface on the sample stage; and
(c) performing plasma processing on the main surface of the semiconductor wafer,
wherein the thin film electrode includes a first portion located lower than the rear surface of the semiconductor wafer, a second portion located higher than the main surface of the semiconductor wafer, and a third portion connecting the first portion and the second portion,
wherein the first portion of the thin film electrode has an overlap region that overlaps the semiconductor wafer in a plan view, and
wherein, at the step (c), high-frequency power is supplied from the high frequency power source to the sample stage and the thin film electrode.

13. The plasma processing method according to claim 12,
wherein the main surface and the rear surface of the semiconductor wafer has a circular shape, and
wherein the overlap region encompasses the whole area of the circumference portion of the semiconductor wafer.

14. The plasma processing method according to claim 12,
wherein a first distance between the rear surface of the semiconductor wafer and the first portion of the thin film electrode in a vertical direction is smaller than a second distance between the end portion of the semiconductor wafer and the third portion of the thin film electrode in a horizontal direction.

15. The plasma processing method according to claim 12, further comprising the steps of:
(d) introducing gas into a processing chamber in which the sample stage is arranged;
(e) introducing a microwave electric field into the processing chamber; and
(f)supplying a magnetic field into the processing chamber.
